(19) United States
(12) Patent Application Publication
(10) Pub. No.: US 2017/0325327 A1
(43) Pub. Date: Nov. 9, 2017

(54) PRINTED CIRCUIT BOARD FOR HIGH POWER COMPONENTS

(71) Applicants: Massachusetts Institute of Technology, Cambridge, MA (US); Hughes Circuits Inc., San Marcos, CA (US)

(72) Inventors: James P. Smith, Chelmsford, MA (US); M. David Conway, Ipswich, MA (US); David Bragdon, Merrimack, NH (US); David B. Du Russel, Maynard, MA (US); Thomas Ferguson, Hudson, OH (US); Jeffrey M. Hughes, San Marcos, CA (US)

(21) Appl. No.: 15/472,704

(22) Filed: Mar. 29, 2017

Related U.S. Application Data
(60) Provisional application No. 62/319,337, filed on Apr. 7, 2016.

(51) Int. Cl. H05K 1/02

(52) U.S. Cl. CPC H05K 1/0206; H05K 1/0284; H05K 1/0272; H05K 1/021; H05K 1/0254; H05K 1/0237; H05K 1/0263

(57) ABSTRACT

A printed circuit board for high-power components includes at least two dielectric layers. A thermally-conductive embedded layer is disposed between two of the dielectric layers and includes one or more internal coolant channels. Thermal vias extend from the embedded layer to an exterior surface of at least one of the dielectric layers. At least one of the dielectric layers in the printed circuit board has an exterior surface on which one or more high power components may be mounted. In some implementations, there are at least two dielectric layers on a same side of the embedded layer and high power components may be located inside the printed circuit board between two dielectric layers. Thermal resistance between the high-power components and the embedded layer is decreased in comparison to typical surface-mounted cold plates, resulting in more efficient heat dissipation. In some implementations the embedded layer is also an electrical ground plane.

### RELATED APPLICATIONS

This application claims the benefit of the earlier filing date of U.S. Provisional Patent Application No. 62/319,337, filed Apr. 7, 2016 and titled “Embedded Thermal Management for High-Power Components on Printed Circuit Boards,” the entirety of which is incorporated herein by reference.

### GOVERNMENT RIGHTS IN THE INVENTION

This invention was made with government support under Contract No. FA8721-05-C-0002 awarded by the U.S. Air Force. The government has certain rights in the invention.

### FIELD OF THE INVENTION

The present invention relates generally to a printed circuit board for high-power components. More particularly, the invention relates to a printed circuit board having an embedded layer with one or more coolant channels to efficiently remove heat generated by high-power components mounted to a surface of the printed circuit board.

### BACKGROUND OF THE INVENTION

High-power components mounted to printed circuit boards can generate significant waste heat. In many circumstances, the waste heat must be dissipated so that the components can be maintained at or below a maximum acceptable operating. For some components, the duty cycle may be limited to maintain a satisfactory operating temperature. Alternatively, a higher operating temperature may be tolerated at the expense of component reliability.

One common technique for cooling high-power components includes the use of a heat sink mounted on the packaging of the component, either with natural convection or with forced convection that can be implemented, for example, with a cooling fan. Typically large heat sinks are employed and thermal performance may be limited such that there may be a substantial difference between the component temperature and the ambient environment.

In another common technique, a cold plate mounted to a back surface of the printed circuit board or mounted to the packaging of the high-power component is used to extract heat. Chilled liquid forced through the cold plate may enable the cold plate to be maintained at a low temperature; however, the component temperature may be significantly higher. For example, the thermal interface resistance between the cold plate and the printed circuit board, or the component packaging, may prevent the component from approaching the cold plate temperature. In addition, the printed circuit board material may have poor thermal conductivity and the component packaging material may include air gaps and/or a material having poor thermal conductivity.

### SUMMARY

In one aspect, the invention features a printed circuit board that includes a first dielectric layer, a second dielectric layer and an embedded layer. The first dielectric layer has a first exterior surface and a first interior surface opposite the first exterior surface. The embedded layer has a first embedded surface adjacent to the first interior surface of the first dielectric layer and a second embedded surface opposite the first embedded surface. The embedded layer includes a thermally-conductive material having at least one coolant channel disposed between the first and second embedded surfaces. The second dielectric layer has a second interior surface adjacent to the second embedded surface of the embedded layer and a second exterior surface opposite the second interior surface. At least one of the first dielectric layer and the second dielectric layer has a plurality of thermal vias that extend between the first exterior and first interior surfaces or the second interior and second exterior surfaces, respectively, and at least one of the first exterior surface and the second exterior surface is configured to receive a surface-mount component.

In another aspect, the invention features a thermally-managed electronics system for high power components. The system includes a printed circuit board and a cooling system. The printed circuit board includes a first dielectric layer, a second dielectric layer and an embedded layer. The first dielectric layer has a first exterior surface and a first interior surface opposite the first exterior surface. The first dielectric layer has at least one electrical component mounted to the first exterior surface, a plurality of electrically-conductive traces on at least one of the first exterior and first interior surfaces, and a plurality of thermal vias extending between the first exterior surface and the first interior surface. The embedded layer has a first embedded surface adjacent to the first interior surface of the first dielectric layer and a second embedded surface opposite the first embedded surface. The embedded layer includes a thermally-conductive material having at least one coolant channel having a coolant channel inlet and a coolant channel outlet. The one or more coolant channels are disposed between the first and second embedded surfaces. The second dielectric layer has a second interior surface adjacent to the second embedded surface of the embedded layer and a second exterior surface opposite the second interior surface. The cooling system is in fluidic communication with the embedded layer and is configured to generate a flow of coolant from the coolant channel inlet to the coolant channel outlet.

### BRIEF DESCRIPTION OF THE DRAWINGS

The above and further advantages of this invention may be better understood by referring to the following description in conjunction with the accompanying drawings, in which like numerals indicate like structural elements and features in the various figures. For clarity, not every element may be labeled in every figure. The drawings are not necessarily to scale, emphasis instead being placed upon illustrating the principles of the invention.

FIG. 1A shows one embodiment of a printed circuit board assembly.

FIG. 1B shows the printed circuit board assembly of FIG. 1A in a reverse and rotated view.

FIG. 2 is an exploded view of the layers of the printed circuit board of FIGS. 1A and 1B.

FIG. 3 is a cross-sectional view of a portion of an embodiment of a printed circuit board.

FIG. 4 shows an exploded view of the embedded layer in the printed circuit board of FIG. 3.

FIG. 5 is a cross-sectional view of a portion of another embodiment of a printed circuit board.

FIG. 6 is a cross-sectional view of a portion of another embodiment of a printed circuit board.

FIG. 7 is a block diagram of an embodiment of a thermally-managed electronics system for high power components.

### DETAILED DESCRIPTION

In brief overview, the invention relates to a printed circuit board for high-power components. The printed circuit board includes at least two dielectric layers. A thermally-conductive embedded layer is disposed between a first one and a second one of the dielectric layers and includes one or more internal coolant channels. Each coolant channel defines a coolant path within a plane that is parallel to the surfaces of the thermally-conductive layer. Thermal vias extend from the thermally-conductive layer to an exterior surface of at least one of the dielectric layers. As used herein, an exterior surface means the layer surface that is farthest from the thermally-conductive layer regardless of whether or not that layer is adjacent to the thermally-conductive layer. An exterior surface is not necessarily an outside surface of the printed circuit board. At least one of the dielectric layers in the printed circuit board has an exterior surface on which one or more high power components may be mounted. In some embodiments, there are at least two dielectric layers on a same side of the embedded layer and one or more high power components may be located inside the printed circuit board beneath the outside surfaces.

Cold plates that are typically mounted on the outside of printed circuit boards to provide cooling for components mounted on an opposite side of the printed circuit board. In the embodiments disclosed herein, the thermally-conductive embedded layer is assembled as part of the printed circuit board fabrication process. Advantageously, high power components can be provided on any exterior surface of a dielectric layer in the printed circuit board. The thermal resistance (temperature rise per unit heat loading; e.g., ° C. per W) between the high-power components and the embedded layer is decreased in comparison to a surface-mounted cold plate, allowing for efficient heat dissipation. Maintaining a high-power component at a lower temperature can enable the high-power component to operate for an extended lifetime and/or to operate at a greater duty cycle for a given operating temperature. In some embodiments, the embedded layer is also used as an electrical ground plane. The printed circuit board is suitable for a variety of applications, including radar, high-performance computing and visualization, and high-energy laser systems. Printed circuit boards having high-power components such as electronic power amplifiers (including radio frequency (RF) amplifiers), field programmable gate arrays (FPGAs), central processing units (CPUs), graphics processing units (GPUs), solid state memory, voltage converters, rectifiers, inverters, and/or resistors and formed according to the principles described herein achieve improved heat dissipation and related advantages.

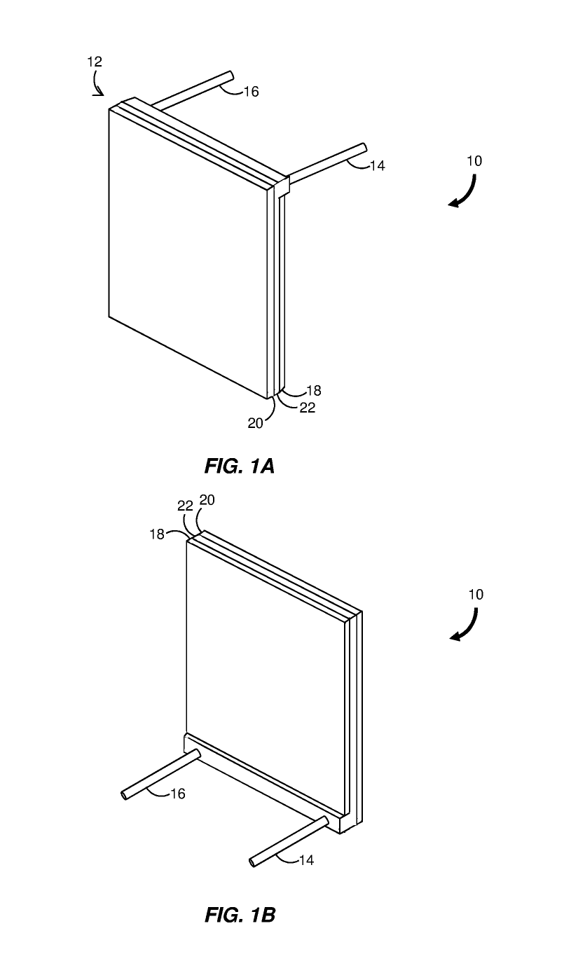

FIG. 1A illustrates one embodiment of a printed circuit board assembly 10 that includes a printed circuit board 12, inlet coolant tubing 14 and outlet coolant tubing 16. FIG. 1B is reverse and rotated view of the printed circuit board assembly 10. The printed circuit board assembly 10 may be used, for example, to thermally manage the operation of high-power components (not shown) mounted to one or both sides of the printed circuit board 12.

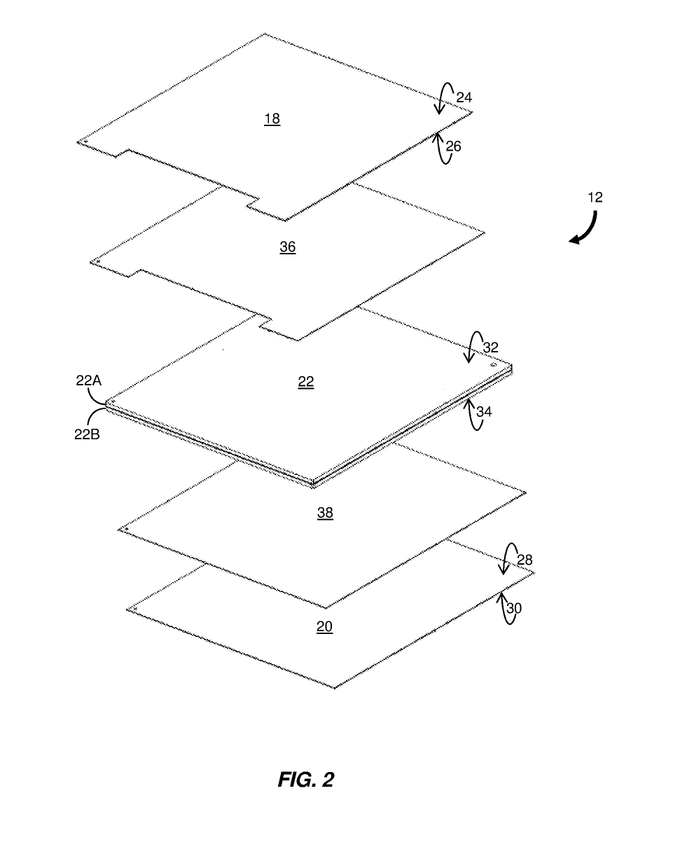

Reference is also made to FIG. 2 which shows an exploded view of the layers of the printed circuit board 12. The layers include a first dielectric layer 18, a second dielectric layer 20 and an embedded layer 22 disposed between the first and second dielectric layers 18 and 20. The first dielectric layer 18 has a first exterior surface 24 and an opposing first interior surface 26. The second dielectric layer 20 has a second interior surface 28 and an opposing second exterior surface 30. The dielectric layers 18 and 20 may be formed of a dielectric material such as a glass fiber epoxy laminate (e.g., FR-4 flame retardant composite material; Rogers R04350™ material available from Rogers Corporation of Rogers, Conn.; Nelco® N4000 series materials available from Nelco Products, Inc. of Fullerton, Calif.); by way of non-limiting examples, the thickness of dielectric layers 18 and 20 typically ranges from 0.008″ (0.203 mm) up to 0.200″ (5.080 mm).

The embedded layer 22 is formed of a material that is thermally conductive. By way of non-limiting examples, the embedded layer 22 may be formed of copper, aluminum (e.g., 6061 aluminum alloy) or other high thermally conductive metal or alloy. Although aluminum may have a lower thermal conductivity, it is sometimes preferable to copper in in applications in which weight is a critical concern. The embedded layer 22 has a first embedded surface 32 that is adjacent to the first interior surface 26 of the first dielectric layer 18 and a second embedded surface 34 that is opposite to the first embedded surface 32 and adjacent to the second interior surface 28 of the second dielectric layer 20. As used herein, “adjacent to” means abutting or next to. For example, surfaces that are adjacent to each other may be in direct contact or may be separated by a thin adhesive film 36 or 38, as described below, used to secure the surfaces to each other. The thickness of the embedded layer 22 can vary according to a particular application and fabrication capabilities. For example, the embedded layer 22 may be less than 0.1 inch (2.5 mm). For higher heat dissipation without stringent weight limitations, the thickness of the embedded layer 22 may exceed 0.5 inch (12.7 mm).

In the illustrated embodiment, the embedded layer 22 includes a coolant channel (not visible) lying between the first and second embedded surfaces 32 and 34. The coolant channel defines a path for a coolant flow in a plane between and parallel to the first and second embedded surfaces 32 and 34. The coolant channel receives a flow of a coolant from the inlet tubing 14 and dispenses the flow of the coolant through the outlet tubing 16. The coolant channel may be along a single “serial” path. Alternatively, the coolant channel may have two or more “parallel” paths through the embedded layer 22 with each parallel path conducting only a portion of the total flow of the coolant received from the inlet tubing 14. In another alternative embodiment, two coolant channels are disposed between the first and second embedded surfaces 32 and 34 and are substantially parallel to each other along their paths. One of the coolant channels conducts a flow of a coolant in a direction that is opposite to the flow of coolant in the other channel. One advantage of this dual coolant channel counterflow configuration is a reduced spatial temperature gradient across the printed circuit board 12.

Dielectric layer 18 has thermal vias (not shown) that extend from the first interior surface 26 to the first exterior surface 24. Alternatively, or in addition, the other dielectric layer 20 has thermal vias that extend from the second interior surface 28 to the second exterior surface 30. Thus the thermal vias can terminate at one end adjacent to one of the embedded surfaces 32 and 34 of the embedded layer 22. The thermal vias can be spatially distributed with respect to the surfaces of the dielectric layers 18 and 20 in a pattern that does not interfere with the location of electrical traces and which improves the flow of heat to the embedded layer 22. The thermal vias can be provided in high spatial densities in locations where significant excess heat is generated, for example, in locations near high power components mounted to one or both of the exterior surfaces 24 and 30.

Two adhesive layers 36 and 38 are used to secure the dielectric layers 18 and 20, respectively, to the embedded layer 22. One adhesive layer 36 is disposed between the first interior surface 26 of the first dielectric layer 18 and the first embedded surface 32 of the embedded layer 22. The second adhesive layer 38 is disposed between the second interior surface 28 of the second dielectric layer 20 and the second embedded surface 34 of the embedded layer 22. The adhesive layers 36 and 38 provide a high-strength bond between the embedded layer 22 and the dielectric layers 18 and 20. The adhesive layer can be an electrically-isolating bond ply material comprising a double-sided pressure sensitive adhesive film. For example, the adhesive layer can be a bond ply composite such as DuPont™ Pyralux® LF bond ply constructed of polyimide film coated on both sides with an acrylic adhesive. The bond ply composite is preferably die cut so that portions of the adhesive layer are removed to avoid interference with the coolant channel, thermal vias and other internal features of the printed circuit board 12. According to one processing sequence, the three layers and intervening adhesive layers are placed in proper arrangement to each other and pressed together (e.g., pressing pressure between 200 psi (1.4 MPa) to 400 psi (2.8 MPa)) and an increased temperature (e.g., between 360° F. (180° C.) to 390° F. (200° C.)) for one to two hours.

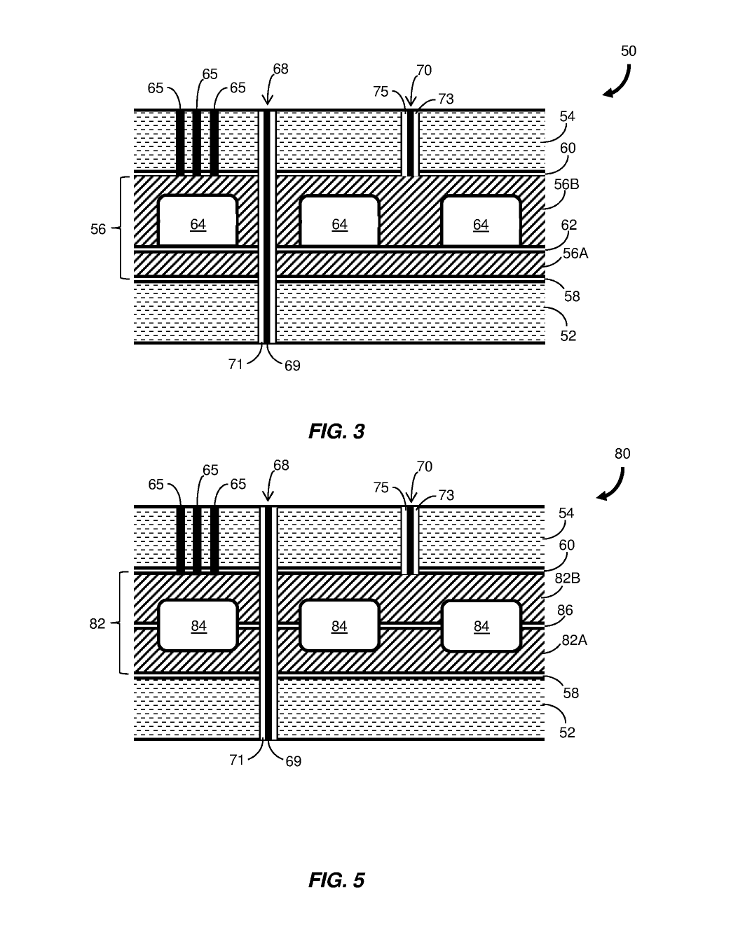

In the illustrated embodiment according to FIG. 2, the embedded layer 22 is shown as two distinct pieces, or sub-layers, 22A and 22B that are bonded together according to a process described below with respect to FIG. 3 to FIG. 5. In other embodiments, the embedded layer 22 is a single piece generated by a different fabrication process such as an additive manufacturing (AM) process (e.g., three-dimensional (3D) printing process).

FIG. 3 is a cross-sectional view of a portion of an embodiment of a printed circuit board 50 having a first dielectric layer 52, a second dielectric layer 54 and an embedded layer 56. The embedded layer 56 is fabricated using conventional machining processes on one or both of an upper plate 56A and a lower plate 56B prior to inclusion in the stack up process for the printed circuit board 50. The machining processes include forming a coolant channel 64 along an interface of the upper and lower plates 56A and 56B. The first dielectric layer 52 is secured to the upper plate 56A with an adhesive layer 58. Similarly, the second dielectric layer 54 is secured to the lower plate 56B using another adhesive layer 60. The coolant channel 64 may be coated with a material that inhibits oxidation without substantially affecting thermal conductivity. For example, the coolant channel 64 may be coated with nickel-phosphorus or nickel-boron alloy using electroless nickel (EN) plating before bonding the upper and lower plates 56A and 56B to each other or using a flow through coating process subsequent to bonding.

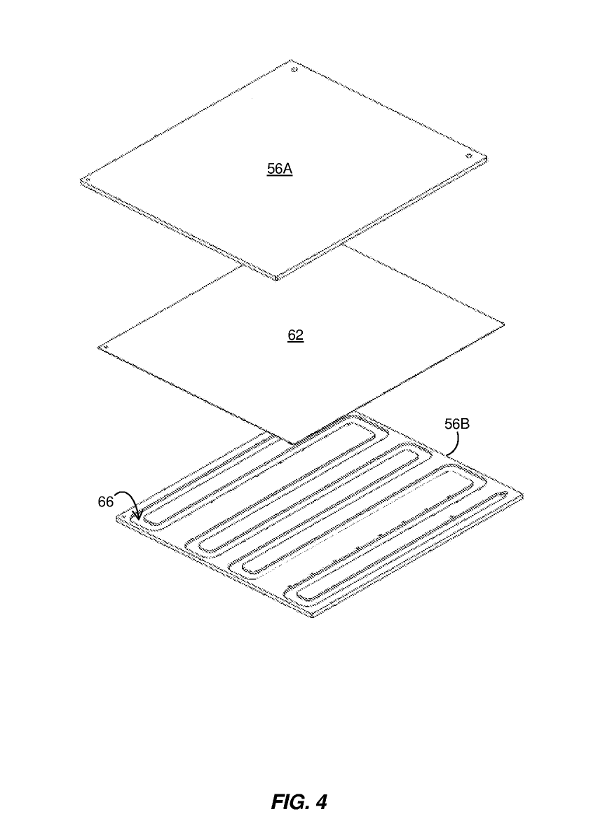

FIG. 4 shows an exploded view of the embedded layer 56 in FIG. 3 in which the lower plate 56B is machined to remove material and thereby form a surface channel 66 that, together with the upper plate 56A, defines the path of the coolant channel 64. The upper and lower plates 56A and 56B are secured to each other using an adhesive layer 62. Although not shown, the adhesive layer 62 may be die cut or laser cut to directly expose the upper plate 56A to the coolant in the coolant channel 64 for improved heat transfer.

Referring again to FIG. 3, the printed circuit board 50 includes thermal vias 65 to conduct thermal energy from the exterior surface of the second dielectric layer 54 to the embedded layer 56. Preferably the thermal vias 65 are formed of solid copper or another high thermal conductivity material. One alternative material is synthetic diamond which may be grown using a chemical vapor deposition (CVD) process. The thermal vias 65 are located at one end close to the coolant channel 64 and at the opposite end at a location arranged to be near to a high-power component (not shown) that generates heat. The number and spatial density of the thermal vias 65 can be selected according to the heat generating characteristics of the component. For example, the spatial density of thermal vias 65 is preferably greatest in regions near components generating the most heat. In some alternative embodiments the dimensions (e.g., diameter) of the thermal vias 65 are varied according to the heat load generated by the high-power component. For example, larger diameter thermal vias may be used in regions close to the high-power components.

The printed circuit board 50 also includes one or more electrical vias 68 that pass through all the layers. The electrical vias 68 can be used to provide electrical power and/or conduct electrical signals to the exterior surfaces (as illustrated) or internal electrically-conductive traces within dielectric surfaces of the printed circuit board 50. For example, the electrical vias 68 may be formed as coaxial vias in which there is a central electrically-conductive path 69 (e.g., a copper conductor) that is electrically-isolated from the embedded layer 56 by a dielectric material 71. An electrical via 68 may be formed by drilling a clearance hole through the full thickness of the printed circuit board 50, filling the hole with a dielectric epoxy and curing the dielectric epoxy. A smaller hole is then drilled through the cured dielectric epoxy and subsequently copper plated to create an RF coaxial connection. By way of non-limiting numerical examples the electrical vias 68 may have a diameter that is less than a few thousandths of an inch (50 um) or more than 0.050 in. (1.3 mm). The locations of the electrical vias 68 are arranged according to the required pass through connections for the various components and circuitry on the exterior surfaces of the dielectric layers 52 and 54, and to avoid interference with the coolant channel 64.

The embed layer 56 can be used as an embedded ground plane. The illustrated portion of the printed circuit board 50 includes a ground plane via 70 that extends from the exterior surface of the second dielectric layer 54, through the adhesive layer 60 and to the embedded layer lower plate 56B. The ground plane via 70 may be formed similarly to the coaxial vias with a central electrically-conductive path 73 surrounded by an electrically-isolating material 75. Ground plane vias may have diameters that are similar to the diameters of the electrical vias 68, although this is not a requirement. Although not shown, one or more ground plane vias may be included between the exterior surface of the first dielectric layer 52 and the embedded layer upper plate 56A. The use of the embedded layer 56 as a ground plane may be in place of or in addition to ground planes on either of the exterior surfaces.

FIG. 5 is a cross-sectional view of a portion of an alternative embodiment of a printed circuit board 80 having a first dielectric layer 52, a second dielectric layer 54 and an embedded layer 82. The embedded layer 82 is fabricated using conventional machining processes on both the upper plate 82A and the lower plate 82B in advance of the stack up process for the printed circuit board 50. The upper and lower plates 82A and 82B are each machined to remove material and thereby form a surface channel in each plate 82. When the plates 82A and 82B are secured to each other, the opposing surface channels define the coolant channel 84. An adhesive layer 86 is used to secure the upper and lower plates 82A and 82B to each other. The adhesive layer may be a bond ply composite that is pre-cut to remove material which would otherwise extend across the coolant channel 84 and be in contact with the coolant.

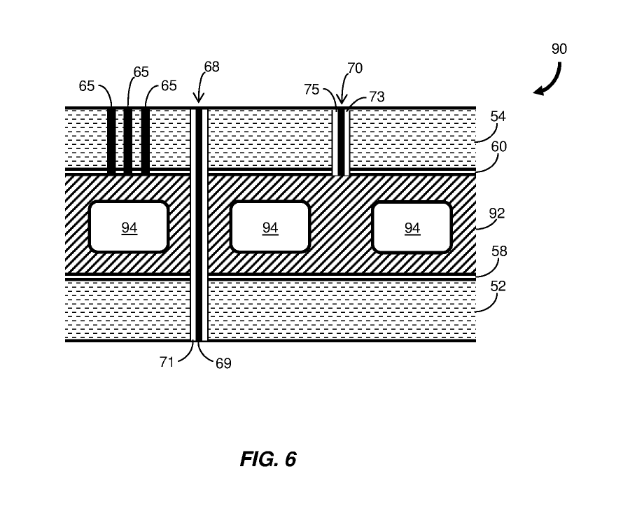

FIG. 6 is a cross-sectional view of a portion of another embodiment of a printed circuit board 90 having a first dielectric layer 52, a second dielectric layer 54 and an embedded layer 92. Unlike the embedded layers 56 and 82 of FIG. 3 and FIG. 5, respectively, the embedded layer 92 is a monolithic layer therefore only two adhesive layers 58 and 60 are used. The embedded layer 92 may be formed of copper, aluminum alloy (e.g., AlSi10Mg) or other thermally conductive materials and printed using a three-dimensional (3D) printing process. The subsequent fabrication process, including the stackup with the dielectric layers is similar to that described above with respect to FIG. 3 and FIG. 5.

Advantageously, the 3D printing process eliminates the need to align upper and lower plates 84A and 84B to each other and more complex channel geometries, which can be difficult to achieve with conventional machining processes, can be accommodated. One example is a lattice mesh coolant channel configuration which allows an increase in the surface area to volume ratio for the coolant channel resulting in improved thermal performance.

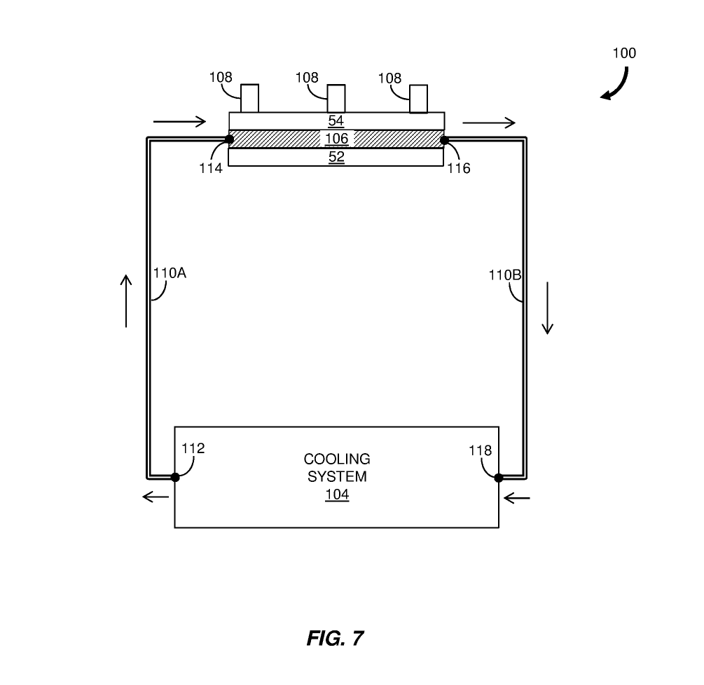

FIG. 7 is a block diagram of an embodiment of a thermally-managed electronics system 100 for high power components. The system 100 includes a printed circuit board 102 and a cooling system 104. The printed circuit board 102 has an embedded layer 106 sandwiched between two dielectric layers 52 and 54, and is populated with high power electrical components 108 on one exterior surface. It will be recognized that in alternative embodiments the high power components may be mounted on both exterior surfaces and/or inside the printed circuit board 102 beneath the exterior surfaces. Not shown are any electrical power sources that may be used to supply electrical power to the high power electrical components 108 and any other electrical components mounted on or included in the printed circuit board 102. Similarly, any signal processors or other processors used to process signals sent to and/or received from the printed circuit board 102 are not shown.

The cooling system 104 is in fluidic communication with the embedded layer 106 of the printed circuit board 102 through fluidic conduits 110. One fluidic conduit 110A conducts a flow of coolant from an outlet 112 of the cooling system 104 to a cooling channel inlet 114 at the embedded layer 106. A second fluidic conduit 110B conducts the coolant that exits the embedded layer 106 at a cooling channel outlet 116 to an inlet 118 of the cooling system 104. For example, the conduits 110 may be metal (e.g., stainless steel, copper, or brass), plastic (e.g., silicone or polyvinyl chloride (PVC)) or rubber tubing. The cooling system 104 may include one or more pumps to pressurize the fluidic path and achieve a particular flow rate of coolant through the printed circuit board 102. In some embodiments the flow rate is determined according to a maximum acceptable variation from an isothermal condition across the printed circuit board 102. A higher flow rate in combination with an embedded layer formed of a highly thermally-conductive material (e.g., copper) generally yields smaller spatial temperature variations across the printed circuit board 102. In one example, the cooling system 104 is a vapor compressor chiller and the fluid supplied to and received from the printed circuit board 102 may be a two-phase refrigerant. In an alternative example, the cooling system 104 provides a chilled liquid such as water or polyethylene glycol. The cooling system 104 may make use of a liquid-to-air heat exchanger, a liquid-to-liquid heat exchanger, or a vapor-compression or absorption refrigeration cycle.

While the invention has been shown and described with reference to specific embodiments, it should be understood by those skilled in the art that various changes in form and detail may be made therein without departing from the scope of the invention. In the various embodiments described above, the printed circuit board includes a single embedded layer between two dielectric channels. It will be recognized that the number of dielectric layers can be greater and that circuitry, electrical traces and/or additional components may be disposed on the surfaces of any internal dielectric layer as well as on the exterior surfaces of the printed circuit board. Moreover, more than one embedded layer of thermally-conductive material and coolant channel(s) may be provided within a printed circuit board according to the principles described above.

What is claimed is:

1. A printed circuit board for high power components, comprising:
a first dielectric layer having a first exterior surface and a first interior surface opposite the first exterior surface;
an embedded layer having a first embedded surface adjacent to the first interior surface of the first dielectric layer and a second embedded surface opposite the first embedded surface, the embedded layer comprising a thermally-conductive material having at least one coolant channel disposed between the first and second embedded surfaces; and
a second dielectric layer having a second interior surface adjacent to the second embedded surface of the embedded layer and having a second exterior surface opposite the second interior surface;
wherein at least one of the first dielectric layer and the second dielectric layer has a plurality of thermal vias extending between the first exterior and first interior surfaces or the second interior and second exterior surfaces, respectively, and wherein at least one of the first exterior surface and the second exterior surface is configured to receive a surface-mount component.

2. The printed circuit board of claim 1, wherein the embedded layer comprises an upper plate and a lower plate and wherein the coolant channel is formed along an interface of the upper and lower plates.

3. The printed circuit board of claim 2 wherein the coolant channel is defined by a surface channel in one of the upper and lower plates.

4. The printed circuit board of claim 2 wherein each of the upper and lower plates has a surface channel and wherein the surface channels are opposite to each other and define the coolant channel.

5. The printed circuit board of claim 2 further comprising an adhesive layer disposed at the interface of the upper and lower plates.

6. The printed circuit board of claim 1, wherein the embedded layer comprises a single plate of the thermally-conductive material.

7. The printed circuit board of claim 6 wherein the embedded layer is fabricated by a three-dimensional printing process.

8. The printed circuit board of claim 1 wherein the thermally-conductive material of the embedded layer comprises copper.

9. The printed circuit board of claim 1 wherein the thermally-conductive material of the embedded layer comprises aluminum alloy.

10. The printed circuit board of claim 1 wherein the coolant channel comprises a serial path from a coolant channel inlet to a coolant channel outlet.

11. The printed circuit board of claim 1 wherein the embedded layer comprises a thermally-conductive material having a first coolant channel and a second coolant channel disposed between the first and second embedded surfaces, the first and second coolant channels being substantially parallel to each other and configured to conduct a flow of a coolant in a first and a second direction, respectively, wherein the first and second directions are opposite to each other.

12. The printed circuit board of claim 11 wherein the coolant channel has a serpentine path.

13. The printed circuit board of claim 1 wherein the coolant channel comprises a plurality of parallel paths disposed between a coolant channel inlet and a coolant channel outlet.

14. The printed circuit board of claim 1 wherein a path of the coolant channel passes under a location for the surface-mount component.

15. The printed circuit board of claim 1 further comprising at least one electrical via that passes through the embedded layer.

16. The printed circuit board of claim 1 further comprising at least one ground plane via that extends from the embedded layer through one of the first and second dielectric layers.

17. The printed circuit board of claim 1 further comprising an adhesive layer disposed between the first interior surface of the first dielectric layer and the first embedded surface of the embedded layer.

18. The printed circuit board of claim 1 further comprising an adhesive layer disposed between the second interior surface of the second dielectric layer and the second embedded surface of the embedded layer.

19. A thermally-managed electronics system for high power components, comprising:
a printed circuit board comprising:
a first dielectric layer having a first exterior surface and a first interior surface opposite the first exterior surface, the first dielectric layer having at least one electrical component mounted to the first exterior surface, having a plurality of electrically-conductive traces on at least one of the first exterior and first interior surfaces, and having a plurality of thermal vias extending between the first exterior surface and the first interior surface;
an embedded layer having a first embedded surface adjacent to the first interior surface of the first dielectric layer and a second embedded surface opposite the first embedded surface, the embedded layer comprising a thermally-conductive material having at least one coolant channel having a coolant channel inlet and a coolant channel outlet, the at least one coolant channel disposed between the first and second embedded surfaces; and
a second dielectric layer having a second interior surface adjacent to the second embedded surface of the embedded layer and having a second exterior surface opposite the second interior surface; and
a cooling system in fluidic communication with the embedded layer and configured to generate a flow of coolant from the coolant channel inlet to the coolant channel outlet.

20. The thermally-managed electronics system of claim 19 wherein the coolant comprises water.

21. The thermally-managed electronics system stem of claim 19 wherein the coolant comprises polyethylene glycol.

22. The thermally-managed electronics system of claim 19 wherein the coolant is a two-phase refrigerant.

23. The thermally-managed electronics system of claim 19 wherein the cooling system comprises a heat exchanger to transfer heat at a location remote to the printed circuit board.
